(19) United States
(12) Patent Application Publication
(10) Pub. No.: US 2006/0148198 A1
(43) Pub. Date: Jul. 6, 2006

(54) Method for forming device isolation region in semiconductor device

(75) Inventor: Dong-Oog Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/320,339

(22) Filed: Dec. 29, 2005

(30) Foreign Application Priority Data
Dec. 31, 2004 (KR) 10-2004-0117737

(51) Int. Cl. H01L 21/76

(52) U.S. Cl. 438/424

(57) ABSTRACT

An exemplary method of forming a device isolation region in a semiconductor device according to an embodiment of the present invention includes forming a sacrificial layer and a hard mask on a substrate; selectively etching the hard mask, the sacrificial layer, and the substrate so as to form a trench; forming a thermal oxide layer on the trench; forming an insulation layer on the thermal oxide layer to fill the trench; polishing the insulation layer and the hard mask so as to leave the hard mask with a predetermined thickness; removing the remaining hard mask and the sacrificial layer; and removing a height difference between the device isolation region and the substrate by partially removing the upper portion of the device isolation region by wet etching.

### CROSS-REFERENCE TO RELATED APPLICATION

This application claims priority to and the benefit of Korean Patent Application No. 10-2004-0117737 filed in the Korean Intellectual Property Office on Dec. 31, 2004, the entire contents of which are incorporated herein by reference.

### BACKGROUND OF THE INVENTION

(a) Field of the Invention

The present invention relates to a semiconductor device. More particularly, the present invention relates to a method of forming a device isolation region in a semiconductor device such as a flash memory device.

(b) Description of the Related Art

A NOR-type flash memory device is a non-volatile memory device, and it has a stacked-gate structure of a floating gate and a control gate. The floating gate and the control gate are stacked on a tunnel oxide layer in the stacked-gate structure. Between the floating gate and the control gate, an interlayer dielectric layer such as an oxide-nitride-oxide (ONO) layer is formed to have a capacitor structure. When the control gate is applied with a bias voltage, the floating gate is applied with the bias voltage according to a coupling ratio. The flash memory device is operated at a relatively high bias voltage for programming and erasing data.

In a typical flash memory device, a device isolation region, a so-called field region that defines active regions, is formed on a semiconductor substrate by a shallow trench isolation (STI) method. In addition, a tunnel oxide layer, a floating gate, an interlayer dielectric layer, and a control gate are sequentially formed on the active region. Word lines, which are gate lines, are formed to cross bit-lines in a layout. A memory cell is formed at a crossing point between a word line and a bit-line. In addition, a bit line contact is formed as a drain contact at an edge portion of the active region.

A process for forming a device isolation region by the STI method includes forming a trench by dry-etching a semiconductor substrate, filling the trench by depositing an oxide layer on the entire surface of the semiconductor substrate, and planarizing the surface by a chemical mechanical polishing (CVD) method.

When the oxide layer on the active region is removed, the device isolation region is completely formed. The device isolation region may have a height difference between the active region and the device isolation region by removal of an insulation layer therebetween. That is, the device isolation region is formed to protrude more than the active region.

In addition, a difference of etch rate between the device isolation region and the active region may cause a divot to be formed at an interface therebetween.

Such morphology may cause residue problems during subsequent processes for forming a floating gate, an ONO layer, and a control gate, so a short circuit between adjacent word lines may occur. A flash memory device having a short circuit may have poor reliability and cause device failure.

In order to prevent the device failure, the height difference and divots at the device isolation region should be minimized.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of forming a device isolation region in a semiconductor device having advantages of minimizing the height difference and divots at the device isolation region so as to enhance the reliability of the device.

An exemplary method of forming a device isolation region in a semiconductor device according to an embodiment of the present invention includes forming a sacrificial layer and a hard mask on a substrate; selectively etching the hard mask, the sacrificial layer, and the substrate so as to form a trench; forming a thermal oxide layer on the trench; forming an insulation layer on the thermal oxide layer to fill the trench; polishing the insulation layer and the hard mask so as to leave the hard mask at a predetermined thickness; removing the remaining hard mask and the sacrificial layer; and removing a height difference between the device isolation region and the substrate by partially removing the upper portion of the device isolation region by wet etching.

In a further embodiment, in the removing a height difference, the device isolation region may be partially removed by a thickness of the remaining hard mask and the sacrificial layer.

In addition, the sacrificial layer may be formed as a thermal oxide layer having a thickness of 10-100 Å.

In addition, the hard mask may be formed as a silicon nitride layer having a thickness of 150-800 Å.

The semiconductor device may be a flash memory device.

The exemplary method of forming a device isolation region in a semiconductor device according to an embodiment of the present invention may further include forming a gate stack by accumulating a polysilicon layer, a dielectric layer, and a polysilicon layer on the substrate.

The dielectric layer may be formed by sequentially forming an oxide layer, a nitride layer, and an oxide layer.

### BRIEF DESCRIPTION OF THE DRAWINGS

FIG. 1 to FIG. 6 are cross-sectional views showing principal stages of a flash memory device according to an exemplary embodiment of the present invention.

### DETAILED DESCRIPTION OF THE EMBODIMENTS

With reference to the accompanying drawings, the present invention will be described in order for those skilled in the art to be able to implement the invention. As those skilled in the art would realize, the described embodiments may be modified in various different ways, all without departing from the spirit or scope of the present invention.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

An exemplary embodiment of the present invention will hereinafter be described in detail with reference to the accompanying drawings.

In an exemplary embodiment of the present invention, when a device isolation region is formed in a semiconductor device (e.g., a flash memory device), a wet etching process is performed after chemical mechanical polishing so that the height-difference between the device isolation region and the active region can be minimized.

An exemplary method of manufacturing a flash memory device will be described in detail with reference to the accompanying drawings.

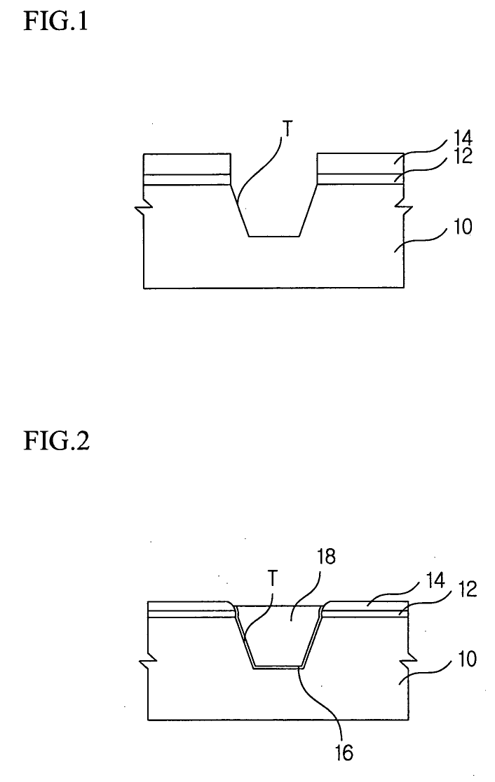

FIG. 1 to FIG. 4 are cross-sectional views showing principal stages of a device isolation region in a flash memory device according to an exemplary embodiment of the present invention.

As shown in FIG. 1, a sacrificial layer 12 having a thickness of 10-100 Å is formed on a semiconductor substrate 10 by a thermal oxidation process. In addition, a hard mask 14 such as a silicon nitride layer having a thickness of 150-800 Å is formed on the sacrificial layer 12 by a CVD process. A second sacrificial layer (not shown) such as a tetraethyl orthosilicate (TEOS) layer may be formed on the hard mask 14 by a CVD process.

The first sacrificial layer 12 is used for releasing stress between the hard mask 14 and the substrate 10. The hard mask 14 may be used as a etch mask for forming a trench and as an etch-stop layer.

Subsequently, the hard mask 14, the sacrificial layer 12, and the substrate 10 are selectively etched to form a trench T.

As shown in FIG. 2, a thin thermal oxide layer 16 is formed on the interior wall of the trench T. The thermal oxide layer 16 is used for enhancing adhesion of subsequent insulating materials on the substrate 10 and recovering damaged portions of the substrate 10 so as to reduce leakage current.

Subsequently, an insulating material such as a high density plasma undoped silicate glass (HDP-USG) is deposited to fill the trench T so as to form an insulation layer. The insulation layer and the hard mask are removed by chemical mechanical polishing (CMP) so as to form a device isolation region 18. At this time, a portion of the hard mask is to be left after CMP.

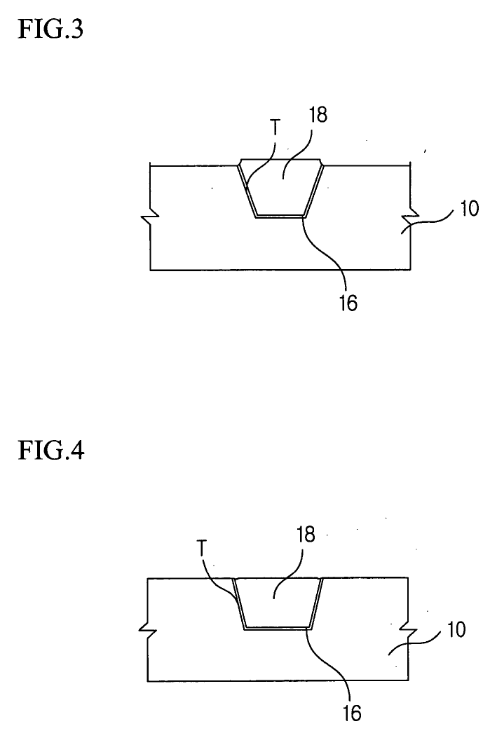

As shown in FIG. 3, the hard mask 14 and the sacrificial layer 12 are removed so as to complete the device isolation region 18.

As shown in FIG. 4, an upper portion of the device isolation region 18 is wet-etched so as to minimize the height difference with the active region.

Flash memory cells can be simultaneously formed with peripheral circuits. At this time, the peripheral circuit regions are covered with a photosensitive layer and only cell regions are exposed and wet-etched. The photosensitive layer (not shown) and the upper portion of the device isolation region 18 are then removed. Subsequently another photosensitive mask is formed on the cell region, and an ion implantation process for adjusting threshold voltage (Vt) is performed. The ion implantation process for adjusting threshold voltage and the wet-etching process of the device isolation region use the same photomask for exposing and developing, so they may have the same pattern.

Such a method for forming the device isolation region can be adopted for typical semiconductor devices as well as flash memory devices.

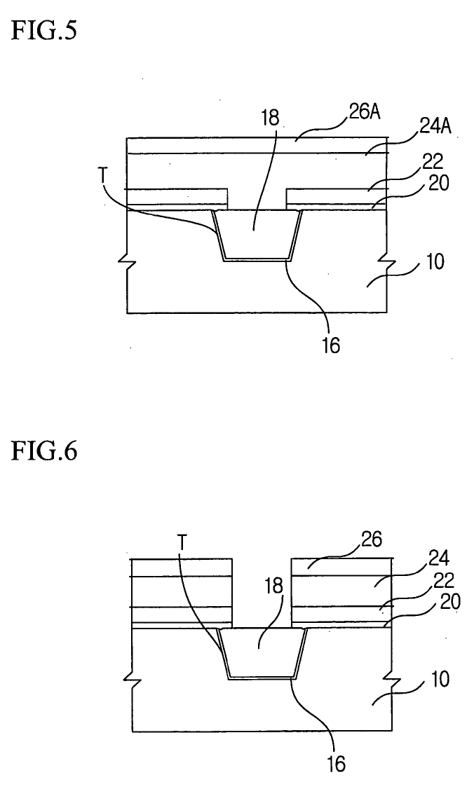

Subsequently, as shown in FIG. 5, an oxide layer is formed on the substrate 10. Doped polysilicon is deposited on the oxide layer, or amorphous silicon is deposited on the oxide layer and doped so as to form a first polysilicon layer of a floating gate.

Next, the first polysilicon layer and the oxide layer are patterned to form a floating gate 22 and a tunnel oxide layer 20.

Then, a dielectric layer 24A is formed by accumulating a nitride layer or an oxide layer. The dielectric layer 24A may be formed by sequentially forming an oxide layer, a nitride layer, and an oxide layer. In addition, a second polysilicon layer 26A is formed on the dielectric layer 24A in the same way as the first polysilicon layer.

At this time, in most regions excluding the flash cell regions, the dielectric layer, the floating gate, and the tunnel oxide layer may be selectively removed before forming a control gate layer.

Subsequently, as shown in FIG. 6, the second polysilicon layer 26A is removed by selective etching so as to form a control gate 26, and the dielectric layer 24A is also etched so as to complete an oxide-nitride-oxide (ONO) layer 24. Consequently, the gate stack in the cell region is completely formed.

A cleaning or ashing process follows in order to remove residues that are generated during forming of the control gate.

As described above, according to an embodiment of the present invention, the height difference and divots in the device isolation region and the active region are minimized by adopting an additional wet-etching process. Accordingly, device failures caused by conductive residues can be prevented, so the reliability of the device can be enhanced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for forming a device isolation region in a semiconductor device, comprising:
forming a sacrificial layer and a hard mask on a substrate;
selectively etching the hard mask, the sacrificial layer, and the substrate so as to form a trench;
forming a thermal oxide layer on the trench;
forming an insulation layer on the thermal oxide layer to fill the trench;
polishing the insulation layer and the hard mask so as to leave the hard mask at a predetermined thickness;
removing the remaining hard mask and the sacrificial layer; and
removing a height difference between the device isolation region and the substrate by partially removing the upper portion of the device isolation region by wet etching.

2. The method of claim 1, wherein, in the removing of a height difference, the device isolation region is partially removed by a thickness of the remaining hard mask and the sacrificial layer.

3. The method of claim 1, wherein the sacrificial layer is formed as a thermal oxide layer having a thickness of 10-100 Å.

4. The method of claim 1, wherein the hard mask is formed as a silicon nitride layer having a thickness of 150-800 Å.

5. The method of claim 1, wherein the semiconductor device is a flash memory device.

6. The method of claim 5, further comprising forming a gate stack by accumulating a polysilicon layer, a dielectric layer, and a polysilicon layer on the substrate.

7. The method of claim 5, wherein the dielectric layer is formed by sequentially forming an oxide layer, a nitride layer, and an oxide layer.
